(19) United States
(12) Patent Application Publication
(10) Pub. No.: US 2026/0130008 A1
(43) Pub. Date: May 7, 2026

(54) PLASMONIC MICRO-LEDS FOR HIGH SPEED COMMUNICATION

(71) Applicant: HYPERLUME INC., Ottawa (CA)

(72) Inventors: Bilal Janjua, Toronto (CA); Hossein Fariborzi, Auburndale, MA (US); Mohsen Asad, Ottawa (CA)

(73) Assignee: HYPERLUME INC., Ottawa, ON (CA)

(21) Appl. No.: 19/060,690

(22) Filed: Feb. 23, 2025

Related U.S. Application Data
(63) Continuation of application No. PCT/CA2024/051451, filed on Nov. 1, 2024.

(51) Int. Cl. H10H 20/812; H10H 20/01; H10H 20/816; H10H 20/821; H10H 20/825

(52) U.S. Cl. CPC H10H 20/812; H10H 20/01335; H10H 20/017; H10H 20/8162; H10H 20/821; H10H 20/825

(57) ABSTRACT

A method for fabricating a high-speed semiconductor device, the method comprising the steps of: providing a light emitting device structure on substrate, activated p-doped; etching grooves on the p-doped layer, partially or fully filling the grooves with noble metal; and constructing at least one top emitting flip chip light emitting device and/or at least one bottom emitting flip chip light emitting device.

### FIELD

Aspects of the disclosure relate to methods for manufacturing semiconductor devices for high-speed communication.

### BACKGROUND

Group III nitrides are compounds formed by nitrogen and one or more Group III elements from the periodic table, such as aluminum (Al), gallium (Ga), and indium (In). These materials have attracted substantial attention in optoelectronics, particularly for use in portable consumer devices like handheld projectors, high-resolution televisions, displays, lighting systems, and high-speed communication technologies.

Among the Group III nitride materials, micro-LEDs are especially valued for their compatibility with a wide range of portable consumer devices, such as handheld projectors, high-resolution televisions, displays, lighting solutions, and high-speed communication systems. The lower thermal resistance of micro-LEDs allows for operation at higher current densities. Since power consumption according to P=I²R, scales quadratically with I, increase in resistance at smaller LED sizes does not dominate the lower current requirements. Thus higher current densities with lower power consumption leads to greater 3 dB bandwidth and improved emission efficiency. Furthermore, their compact size enables the integration of micro-LED arrays, which significantly boosts system throughput.

However, significant challenges remain in the fabrication of GaN-based micro-LEDs, including high material defect densities (around 10⁹ defects per cm²) and strong intrinsic polarization fields (in the megavolt-per-centimeter range), both of which lead to efficiency losses at a wide range of current densities. GaN epitaxy is typically grown on substrates with considerable lattice mismatch, such as sapphire, silicon, or silicon carbide (SiC), which may result in misalignment and asymmetry between the substrate and GaN layer, and increases the incidence of material defects.

In addition, polarization is an inherent, non-centrosymmetric property of GaN crystals. In the typical <0001> growth direction, wurtzite (hexagonal) phase GaN displays distinct polarity, which negatively impacts LED recombination characteristics by causing inefficient recombination between misaligned electron and hole wavefunctions.

Recently, significant efforts have focused on improving the emission efficiency of InGaN/GaN multiple quantum wells (MQWs) by coupling them with surface plasmons (SPs). In 1999, Gontijo et al. predicted that when surface plasmons (SPs) are resonantly excited in metal nanostructures, the spontaneous emission rate (SER) of the emitter could be enhanced by over 1000 times, with the resulting evanescent field influencing the emitter [1]. When a metal layer is placed near a quantum well (QW) and the bandgap energy of the quantum well is close to the energy of the SPs, energy can be transferred to the SPs at the metal interface, creating surface plasmon polaritons (SPPs) or localized surface plasmon (LSP). This energy transfer increases electron-hole recombination rates and enhances spontaneous emission, improving internal quantum efficiency (IQE) and extraction efficiency and speeding up carrier dynamics. To emit light from SPPs, momentum matching is required, which can be achieved by texturing the metal layer through diffraction gratings or rough surfaces.

A recent demonstration of a light-emitting hyperbolic metasurface, utilizing nanostructured silver (Ag) and indium gallium arsenide phosphide (InGaAsP) quantum wells, highlights the potential of III-V compound semiconductors as promising candidates for developing LEDs that are both efficient and fast. Several studies have reported improved emission efficiency of InGaN/GaN multiple quantum wells (MQWs) in the blue-light spectral region through quantum well-surface plasmon (QW-SP) coupling. Okamoto et al. demonstrated a 14-fold increase in blue emission using bottom excitation and detection from a silver (Ag)-coated sample with a 10-nm GaN spacer layer between the InGaN QWs and the silver layer [2]. Furthermore, the anisotropic polarization response of the metasurface can enhance the transmission rate of LEDs used in visible light communication (VLC) by providing an additional degree of freedom using light polarization for encoding information.

However, these designs are impractical for devices due to poor p-doping and light-blocking effects. Kwon et al. embedded Ag particles near the n-GaN/MQW interface for improved device operation, however, there were challenges such as process interruptions, impurity risks, and poor crystal quality [3]. J. Henson's work with silver nanocylinder arrays showed near-green light enhancement but also required a thin spacer layer for efficient SP coupling, making it less feasible for practical devices [4]. Overall, while SP coupling shows potential for improving LED efficiency, numerous challenges remain for practical implementation, including reliability and radiative efficiency issues. Currently, the total light output power from these devices remains unknown.

It is well known that metal dissipation losses, caused by ohmic loss, electron-hole pair generation, and high-order SP modes, are significant. Therefore, to improve the efficiency and carrier dynamics of an LED, the increase in SP based enhancement must exceed the losses in the metal. SP technology is an effective method for boosting EQE in low-efficiency emitters, such as micro-LEDs with reduced efficiency due to surface nonradiative recombination having large surface to volume ratio. SPs can also enhance the bandwidth of LEDs in visible light communication (VLC) applications. Although theoretically, LED modulation bandwidths could reach tens of GHz, in practice, the bandwidth achieved through SP enhancement rarely exceeds twice that of conventional LEDs. Achieving SP-enhanced devices with both high spontaneous emission rates (SER) and EQE remains a practical challenge.

### SUMMARY

In one of its aspects, a method for fabricating a semiconductor device, the method comprising the steps of:
providing a substrate;
patterning nanoholes through a p-doped GaN layer down towards a multiple quantum well (MQW) emitting region of a noble metal;
depositing a nanostructured noble metal film in the nanoholes.

In another aspect, a method for fabricating a semiconductor device, the method comprising the steps of:
providing a substrate;
activating a top p-doped layer comprising at least one step of metal deposition, rapid thermal annealing and chemical wet etching;
etching features into the p-doped layer using a thin dielectric and resist as a mask;
depositing a passivation layer and/or a noble metal into the etched features;
and fabricating the semiconductor device a flip chip bonding process.

In another aspect, a method for fabricating a semiconductor device, the method comprising the steps of:
providing a substrate;
activating a top p-doped layer;
etching grooves on the p-doped layer;
partially or fully filling the grooves with a metal; and
fabricating the semiconductor device via a flip chip bonding process.

In another aspect, a semiconductor device comprising:
on a substrate, a light emitting device (LED) epi-structure comprising
   a n-doped layer,
   a multi quantum well (MQW);
   a p-doped layer,
   an active region;
   a metal on top of the p-doped layer;
   etched features within the p-doped layer with various 3D geometric shapes to improve plasmonic coupling.

There is provided high bandwidth and high efficiency Group-III nitride-based devices and methods for their fabrication. These devices offer a cost-effective approach to utilizing high speed communication. In addition, these devices overcome the inherent slow spontaneous rate limitation associated with polar-GaN based LEDs. While gallium nitride (GaN) material is referenced in the devices, it serves as an example only. The methods herein are equally applicable to any Group III-V or other material containing both hexagonal and cubic phases.

The methods disclosed herein address the aforementioned problems by introducing plasmonic effects which reduce the radiative rate lifetime. In one example, the method comprises patterning a p-doped layer to create holes and depositing noble metal inside the holes. In various embodiments, this processing technique results in complete surface texturing of noble metal filled holes achieved through deliberate etching, and depositing noble metal within vertical or angled holes inside the p-doped layer, and yields a plasmonic III-Nitride device structure via p-doped layer patterning and deposition.

One benefit of utilizing plasmonic nanoparticles in device manufacturing, as outlined herein, is the capacity to seamlessly integrate Group III nitride materials, such h as GaN with silicon complementary metal-oxide semiconductor (CMOS) materials, which are both widespread and cost-effective.

The near-field coupling between the multiple quantum well (MQW) emitting region and the p-GaN/noble metal interface, which supports surface plasmon, is maximized when the distance between them is minimized. This distance, of plasmonic nanoparticle from the nearest quantum well, is preferably less than the penetration depth of the surface plasmon in GaN, which is typically less than 50 nm at a wavelength of 450 nm.

Conversely, to maximize adequate electronic transport, the p-GaN layer is preferably thicker than the depletion width on the p-side of the diode, which is approximately more than 50 nm with reasonable doping levels in the p and n region.

To resolve this inherent challenge, previous researchers have explored alternative designs, such as embedding Ag nanoparticles in undoped GaN experimentally or proposing side-emitting microtubule-based devices theoretically. In contrast, the present disclosure describes a method of patterning nanoholes through the p-GaN layer down to the MQW region, followed by coating the nanoholes with a thin noble metal film. This solution takes advantage of the nanostructured noble metal film, which is crucial for coupling surface plasmon thus increasing radiative recombination rates without sacrificing significantly p-contact resistance.

Furthermore, the device described herein separates the plasmonic LED into two regions: a “plasmonic” region, consisting of the nanoholes or etched region with metal where the distance between the MQW and the noble metal film may be precisely controlled, and an “electronic” region, free of nanoholes, where the diode's electrical behavior is preserved. This approach allows for an effective trade-off between plasmonic enhancement and electronic performance, although optimizing the geometry of the nanoholes is desirable to maximize surface plasmon excitation and coupling.

### BRIEF DESCRIPTION OF THE DRAWINGS

Several exemplary embodiments of the present disclosure will now be described, by way of example only, with reference to the appended drawings in which:

FIG. 1 shows a cross-sectional view of a LED epi-structure on a substrate having an activated p-doped layer;

FIG. 2A shows a cross-sectional view of the etched featuring in the p-doped layer;

FIG. 2B shows a cross-sectional view of the LED epi-structure with noble metal deposited in the etched features;

FIG. 2Ci shows a cross-sectional view of the LED epi-structure with etched features with noble metal nanoparticles deposited in features with a positive sloped sidewall;

FIG. 2Cii shows a cross-sectional view of the LED epi-structure with etched features with noble metal nanoparticles deposited in features with a negative sloped sidewall;

FIG. 2D shows a cross-sectional view of the LED epi-structure with etched features having a noble metal deposited on an intermediate layer;

FIG. 2E shows a cross-sectional view of the LED epi-structure with etched features having a noble metal completely filling the features;

FIG. 3 shows a standard top emitting light emitting device with embedded plasmonic structures and both contact accessible from a top surface;

FIG. 4A shows a flip chip bonded light emitting device with partially filled embedded plasmonic structures;

FIG. 4B shows a flip chip bonded light emitting device with filled embedded plasmonic structures;

FIG. 4C shows a flip chip bonded light emitting device with partially filled embedded plasmonic structures separated by a transparent conductive oxide;

FIG. 5A shows a flip chip bonded light emitting device with partially filled structures on the p-side and etched surface on n-side covered with noble metal; and

FIG. 5B shows a flip chip bonded light emitting device with partially filled structures realized on both side of the active region.

### DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

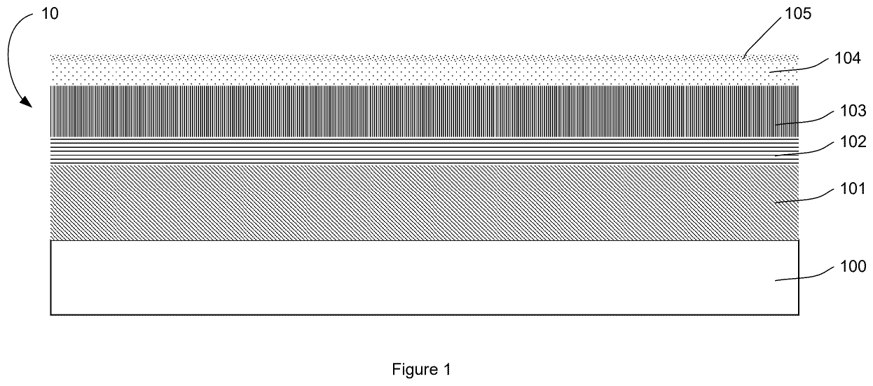

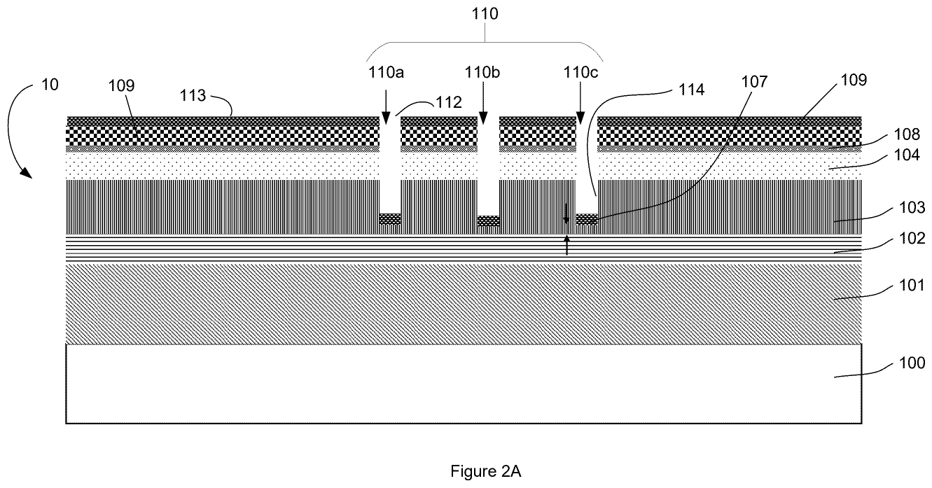

In FIG. 1, there is shown a semiconductor device 10 fabricated on substrate 100 fabricated. The substrate 100 comprises a compatible material such as sapphire single or double side polished, patterned sapphire, silicon, free standing GaN, silicon carbide etc. The semiconductor device 10 may comprise a light emitting device standard structure comprising a n-doped layer 101, a multi quantum well (MQW) 102, a p-doped layer 103, an activated region 104 formed by performing an annealing step with a metal scheme 105 on top of p-doped layer 103. The multi quantum well 102 may comprise one or more quantum wells having thickness ranging from sub nanometre up to tens of nanometers. The semiconductor device 10 may comprise additional layers (not shown) such as, a buffer layer, a superlattice strain relief layer, a low doped high material quality n-doped layer, a high doped low temperature grown p-doped layer 103, a heavily doped high temperature grown p-doped layer 103, and an aluminium gallium nitride base, bandgap electron blocking layer, and so forth.

The metal scheme 105 comprises a bilayer stack based on nickel and gold having thicknesses ranging from few nanometers to tens of nanometers. The metal layer 105, after rapid thermal anneal in nitrogen and oxygen environment, may be removed via wet etching or any other compatible etching process. The activated layer 104 consists of the p-doped layer 103 having higher free carriers resulting in reduced depletion capacitance and lower resistance.

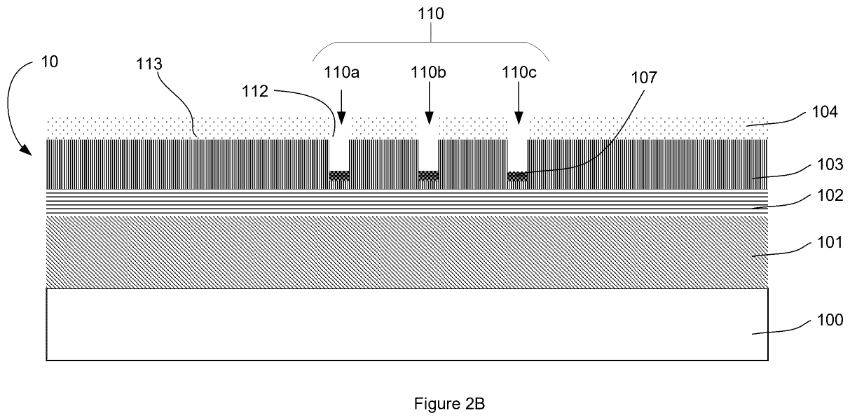

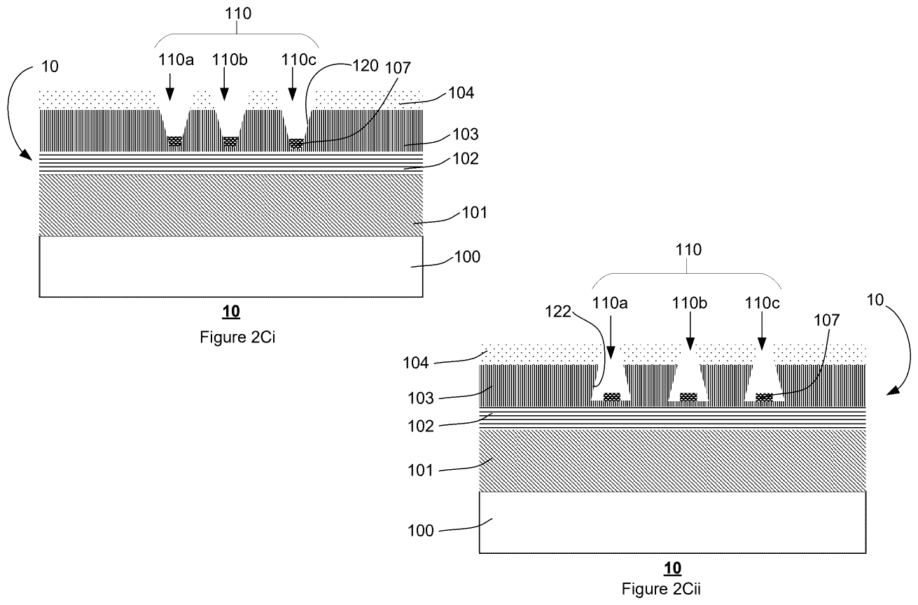

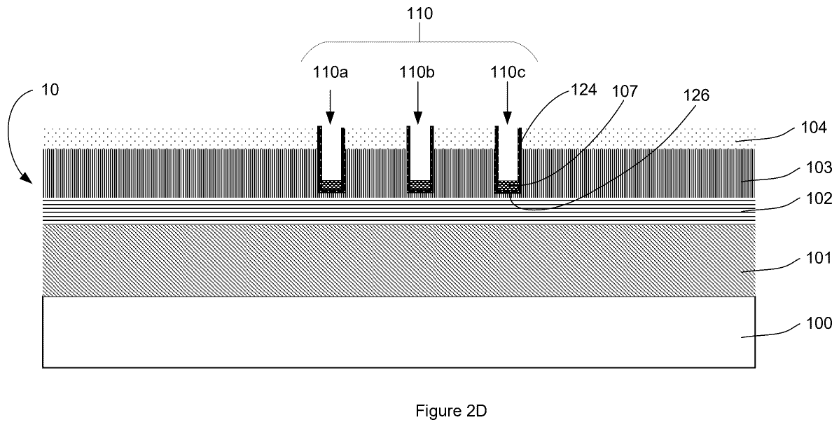

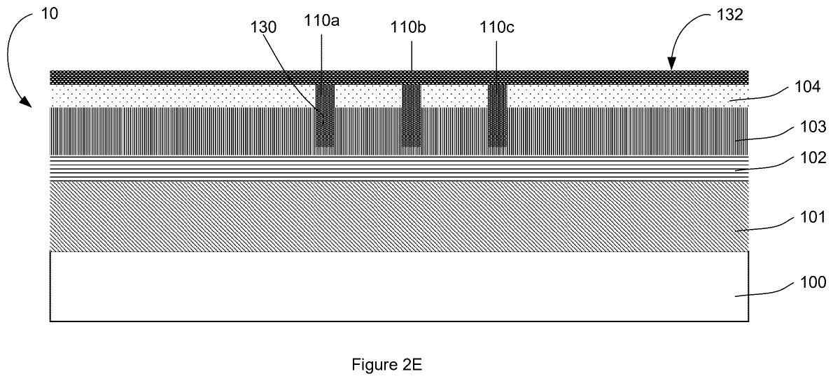

In FIG. 2A, a array 110 of holes on top of the activated p-doped layer 103 is realized using standard lithography process. The holes or features may be patterned in the unetched surface 113 using E-beam lithography, nanoimprint and laser interference lithography followed by dry etching including plasma or ion milling or wet etching to form an etched surface 112. The etched surface 112 may be designed to be smooth or with designed roughness. The holes or etched features 110a-c can take any shape and size. The shape of the holes 110a-c may include a circle, an ellipse, a rotated ellipse, a square, and a rectangle, among others. The size of the holes 110a-c may range from tens of nanometers to hundreds of nanometers. The shape of the features 110a-c may be modified in the growth direction by changing the etching chemistry. The pattern in which the etched features 110a-c are realized may be a square, triangle, hexagonal etc lattice. Converting SPP energy into light emission requires adjusting the wave vector (momentum) of the SPPs to match that of the emitted light due to the existing momentum mismatch.

The momentum (wave vector) of surface plasmon polaritons (SPPs) is generally greater than that of light, which inhibits the direct coupling of light from SPPs on a perfectly smooth surface. However, this momentum mismatch may be addressed by utilizing a subwavelength two-dimensional noble metal array. Thus, the period for the square lattice adopted may be modified from 150 nm all the way to 500 nm to enhance the SPP formation.

In one example, random patterns using dielectric nanoparticles as hard mask may be realized. In addition, asymmetric etched features can help break structure symmetry and enhance light coupling. The lattice period may also be designed to act as spectral or polarization filter. An etched sidewall 113 may comprises a positive, normal or a negative angle, and the etch depth in the noble metal 107 is determined by the spacing 106 between the etched surface 112 from the MQW 102 and the thickness of the p-doped layer 103. In one example, the spacing 106 is designed to be less than 50 nm at a wavelength of 450 nm to maximize plasmonic field having strong overlap with the active region 104.

A metal layer with surface texture, such as a designed diffraction grating, periodic arrays, or random roughness, can meet this requirement by altering the momentum, enabling effective light emission from the SPP mode. The surface plasmon frequency may be tailored not only by adjusting the sizes of nanoparticles and the geometry or periodicity of metallic nanostructures, but also by employing different metallic configurations.

In one example, at least three parameters govern the interaction between the MQW 102 and the nanopatterned noble metal film 107, that is, the feature opening area, feature shape, the features pitch, and the etch depth. In one study, these features were experimentally modified and optimized in plasmonic LED fabrication while ensuring effective MQW-nanostructure coupling.

The surface plasmonic spacing 106 may be estimated using the following equation:

$${d}_{plasmonic} = \frac{{λ}_{o}}{2 π} \sqrt{\frac{{ε}_{GaN}^{′} - {ε}_{Nobel Metal}^{′}}{{ε}_{GaN}^{′2}}}$$

For wavelengths at 450 nm and having silver as nanoparticles this depth is less than 40-50 nm, which illustrates substantially precise control of the etch rate to ensure maximum coupling between the nanoparticle and the active region.

If the etched surface 112 is intentionally roughened, additional plasmonic effects may be introduced. Having a metal layer on top creates localized plasmonic effects near the quantum wells.

In one example, the device 10 is designed to emit from the p-doped side 103, as such, a thin dielectric layer 108 and resist 109 may be used as a mask to etch features. Noble metals 107 such as aluminum (having response in ultraviolet wavelength), silver (having response in visible wavelength) etc. can then be deposited. The thickness of the noble metal 107 may be few nanometers to hundreds of nanometers. The thickness may be optimized to make the plasmonic field resonant with the MQWs 102 excited states thus maximizing the plasmonic coupling effect.

In another example, the thickness of the p-doped layer 103 may be estimated using this relationship:

$${d}_{pdepletion} = \sqrt{\frac{2 {ε}_{GaN}^{′} {V}_{bi} {N}_{D}}{{qN}_{A} ( {N}_{A} + {N}_{A} )}}$$

For doping level on the n-side of 5⁻¹⁸ cm³ and p-side 5⁻¹⁸ cm³ or higher, depletion region on p-side is approximately 70-80 nm. The thickness of this layer 103 may be reduced by increasing the dopant densities on the p-side (NA). Another technique adopted to reduce this layer is to activate the p-doped surface prior to fabrication of the device 10 based on the steps discussed earlier. A thinner p-side depletion width reduces the required etch depth needed to match the criteria set by the SP penetration depth. In addition, thinner p-side depletion width permits a realization of a feature with a smaller size. This allows for realistic aspect ratios (feature area to etch depth) thus significantly reducing etching complexity.

The depth of the etched holes 110a-c is a substantial parameter in this structural design, as the photoluminescence (PL) intensity of a noble metal-coated LED 10 is highly dependent on the distance between the multiple quantum wells (MQWs) 102 and the metal layer 107, due to the exponential decay of the surface plasmon (SP) evanescent field. The luminescence intensity shows exponential increases, as the spacing 106 thickness decreases. This dependence of PL enhancement on spacer thickness aligns with the SP-QW coupling model.

In one study, a standard blue/violet LED epitaxial wafer featuring a 120 nm-thick Mg-doped p-GaN layer is used. Photoluminescence measurements at room temperature determine the emission wavelength to be 405 nm-450 nm. The design itself is not restricted to these wavelengths. The etch depth is optimized to 90 nm, 30 nm away from the nearest quantum well 102. The multiple quantum wells (MQWs) 102 in the device 10 remain intact, ensuring that the internal quantum efficiency (IQE) of the active layers 104 is not compromised by the etching process.

In FIG. 2B, the resist 109 and thin dielectric 108 can then be used to lift off unwanted noble metal from the unetched surface 113. A noble metal 107 such as aluminum, copper, silver and gold, may be deposited in the etched holes 110a-c. Using negative resist from previous step in a self-aligned process silver from unetched surface 113 may be removed. This step may be done using E-beam deposition. Generally, the thickness of the metal 107 determines size of the nanoparticle inside the hole 110a, 110b or 110c. If the hole 110a, 110b or 110c is a circle, then cylindrical nanoparticles are realized. Similarly, the pattern of the holes 110a-c and the array 110 may be optimized for best results. Asymmetric structures can also be utilized to break symmetry of the system, thereby resulting in improved light extraction and faster carrier decay times.

In FIG. 2Ci, a sidewall angle of the etched p-doped layer 103 is comprises a positive angle 120. This may be achieved by changing the etching chemistry or by using wet etching. The positive angle 120 allows for etched features 110a-c that are smaller than the exposed pattern, which leads to a more enhanced field in proximity to the MQWs 102. Meanwhile, FIG. 2Cii shows a sidewall angle of the etched p-doped layer 103 with a negative angle 122 profile, which helps to reduce the semiconductor/metal interface thus reducing surface recombination. In addition, the negative angle 122 helps to reduce contact resistance.

In FIG. 2D, an intermediate layer 124 is inserted before depositing the noble metal 107. The intermediate layer 124 may comprise a metal layer 107 such as nickel, chromium etc. to improve adhesion of the noble metal 107, and may also comprise an intermediate layer 124 comprising a dielectric or passivation layer such as aluminium oxide, silicon oxide, silicone nitride etc. to reduce surface recombination at the interface 126. The thickness of the intermediate layer 124 may be kept small to minimize interference with the plasmonic coupling between the noble metal 107 and the MQW 102.

At high forward bias, the injection of carriers into the active region 104 increases significantly, resulting in higher carrier densities. This leads to an accumulation of excess minority carriers (electrons on the p-side in nitride LEDs), which increases the charge stored

$$\frac{{qAn}_{i}^{2} {L}_{n}}{{N}_{A}} ( {e}^{\frac{{V}_{d}}{{V}_{T}}} - 1 )$$

and corresponding diffusion capacitance

$${C}_{d} \approx \frac{{I}_{d} ( @ {V}_{D} )}{{V}_{T}} .$$

A larger diffusion capacitance means that more charge must be stored or released for a given change in voltage, raising the device 10's time constant τ=RC, where R is the resistance and C is the capacitance. An increased time constant slows the device 10's response. Under high bias conditions, the diffusion capacitance can dominate, making it harder for the device 10 e.g. LED, to keep up with high-frequency input signals. This limits the LED 10's performance in applications requiring rapid modulation, such as high-speed data communication. In nitride LEDs, polarization fields exacerbate the issue by causing carrier leakage and accumulation, further increasing the diffusion capacitance. The etched features with a sidewall help deplete the minority carrier faster thus reducing the diffusion capacitance.

In FIG. 2E, noble metal 130 is deposited after removing the resist etch mask. The features are filled with noble metal 130. This allows the noble metal 130 to completely cover both the etched feature 110a-c and the unetched p-doped layer 103. The noble metal 130 than can serve multiple purposes. While allowing plasmonic effect in proximity to the active region 104, the noble metal 130 layer can also be made to form an ohmic contact using the right annealing conditions. Additionally, the noble metal layer 130 can serve as a reflective layer, significantly enhancing light extraction efficiency in devices with bottom-side emission, such as flip-chip LEDs.

This surface plasmon energy coupling mode provides a high density of states and a rapid coupling rate, which facilitates a fast pathway for electron-hole recombination. The methods described herein aim to further boost light emission by combining the increased light extraction efficiency (LEE) achieved through hole-array patterns with the enhanced internal quantum efficiency (IQE) resulting from quantum well (QW) and surface plasmon (SP) coupling, enhanced radiative recombination rate.

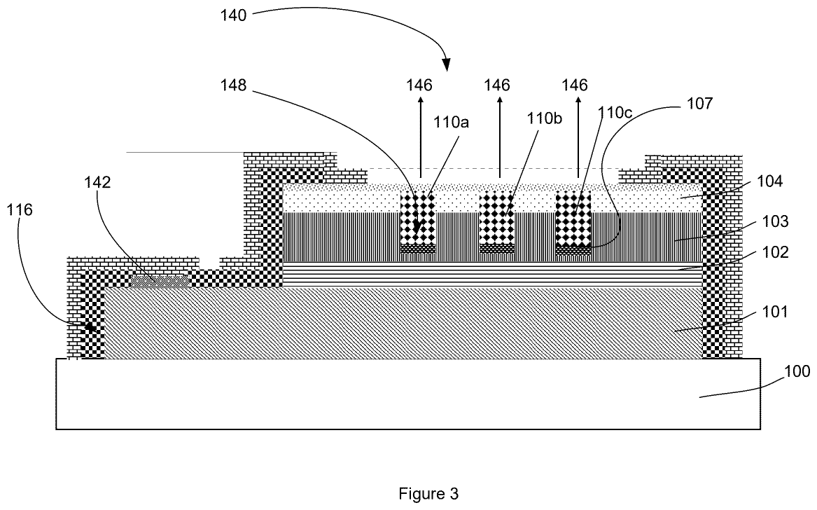

In FIG. 3, in one example, there is shown a semiconductor device 140 fabricated on a substrate 100 comprising deposition of a p-contact 142 which may comprise chromium, gold, nickel-gold, palladium, palladium-nickel-gold, nickel-indium tin oxide or any other metal scheme compatible with semiconductors to form ohmic contact. This allows improved injection of holes 110a-c into the device 140 structure. In one example, the semiconductor device 140 is a standard top emitting device realized having plasmonic features embedded in a mesa. The mesa may be any size ranging from a few microns up to hundreds of microns, and the mesa may comprise a variety of shapes. Depending on best alignment the etched features 110a-c can cover a majority or a part of the mesa area. The etch depth of the mesa may be dimensioned such that it does not to reach the n-doped layer 101. Both the n contacts 142 and the p contacts 144 are realized on the same side. The device 140 emits from the top with emission wavelength 146 determined by the MQW 102 excited states and resonance wavelength of the plasmonic structures coupling. If the plasmonic features are implemented as a lattice that meets the Bragg condition, these features can act as a spectral filter and can influence both the emission wavelength and its spectral linewidth.

The plasmon energy of silver is ˜3.76 eV, but for Ag/GaN surface coatings, this energy may be adjusted to ˜3 eV (approximately 410 nm) when considering the dielectric constants of Ag and GaN. Therefore, silver is suitable for SP coupling with violet/blue emission, and in turn significant increase in luminescence intensity is attributed to the resonant SP excitation. Thin dielectric layers 148 may be placed as intermediate layers with which this resonance energy may be more finely tuned. Plasmonic nanoparticles can interact with the environment bigger than their own and is dictated by the scattering and absorption cross sectional area. The cross section area can be increased significantly by optimizing the shape, dimension and the environment surrounding them. With enhanced cross sectional area, the density of nanoparticles can be reduced significantly on the top or bottom of the device resulting in significantly lower resistance and sidewall related losses.

The individual devices can then be electrically interconnected either in parallel, series, or any hybrid configuration. In numerous electronics and optics applications, it may be beneficial to link multiple adjacent micro-LEDs in parallel or series or combination of both to enhance the output power while also maintaining high speed. Moreover, certain electronics applications may necessitate an alternative electrical arrangement, mirroring the common practice seen in modern integrated circuits. top contact may be a transparent conductive oxide or a semi-transparent metal.

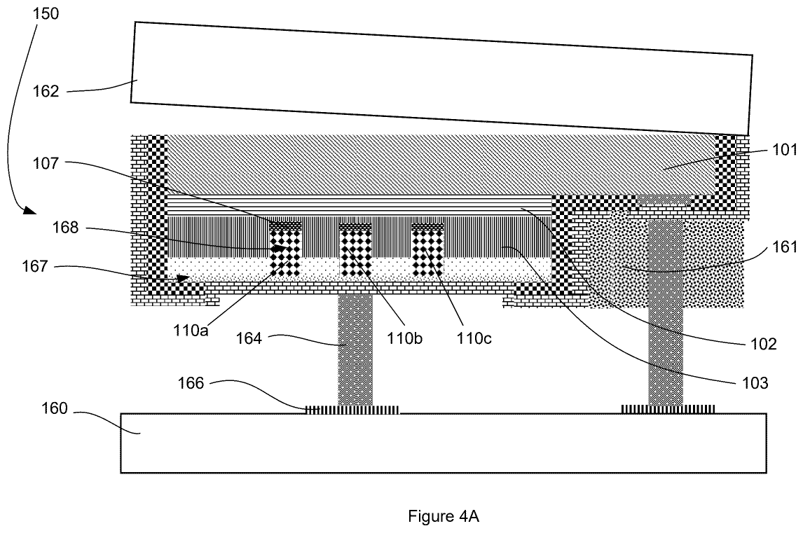

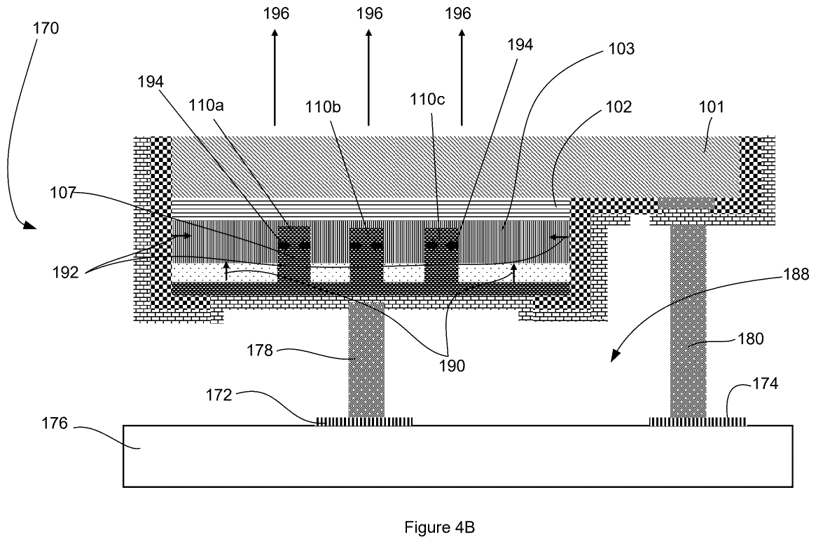

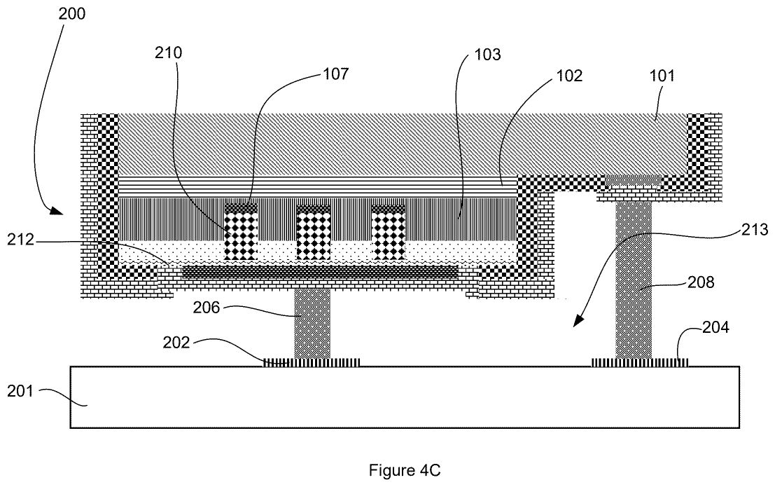

In FIG. 4A, there is shown a semiconductor device 150 fabricated comprising first edge trimming to facilitate the wafer bonding process with a CMOS substrate 160 via a suitable adhesive, such as, benzocyclobutene (BCB), among others. The adhesive layer 161 may comprise shock absorbing capabilities which may be beneficial during the laser liftoff process. The semiconductor device 150, such as a mounted flip chip optical device structure, in one example, comprises an interconnect CMOS board 160 of the type known to those skilled in the art of electrical connection of the LED. In one example, the mounted flip chip optical device structure 150 is fabricated comprising removal of substrate 162 using a suitable technique such laser liftoff. The process requires precise alignment over the CMOS substrate 160 to ensure the solder bumps 164 are aligned with the contact pads 166 on the substrate 160. To perform an ohmic contact with the activated p doped GaN layer a metal schemes 167 based on nickel and gold or containing indium tin oxide or other metal can be implemented. The flip chip LED structure 150 provides access to the light path. In the flip chip structure 150, the plasmonic nanoparticles 107 are separated from the p-contact using a dielectric layer 168.

In FIG. 4B, there is shown a semiconductor device 170 comprising contact pads 172, 174 on both the CMOS chip and substrate 176, often referred to as bump bond metallization. Several methods such as sputtering, vapor deposition, or electroplating may be utilized for their deposition. This metallization facilitates efficient electrical contact and provides a surface suitable for a molten solder alloy. Subsequently, solder bumps 178, 180 may be formed on the contact pad 172, 174, respectively, located on the chip's relevant surface, employing various growth techniques, with electroplating being the predominant method. The process requires precise alignment over the substrate 176 to ensure the bumps 178, 180 are aligned with the contact pads 172, 174 on the substrate 176. Following remelting and soldering, the gaps 188 may be filled with electrically insulating adhesive. Thermal compression bonding is an alternative. The device 170 emits from the top with emission wavelength 196 determined by the MQW excited states and resonance wavelength of the plasmonic structures coupling.

The etched patterns 110a-c are filled with a reflective noble metal 107, which allows light having a reflection 190 and 192. Enhancing light retention within the structure increases the likelihood of extracting light from the top surface. The same noble metal 107 may be used to form an ohmic contact with activated surface, the filled etched structures 110a-c also help extract heat 194 from the highly resistive p-doped layer 103 at higher current densities. The noble metal layer 167 covering the p-doped layer 130 may act as a thermal heat sink while also providing light reflection. For micro-LEDs working at higher current densities better heat dissipation results in reduced thermal droop, improved light extraction efficiency and faster carrier dynamics.

In FIG. 4C, there is shown a semiconductor device 200 fabricated on substrate 201, with contacts 202, 204 and solder bumps 206, 208 may be formed thereon. The plasmonic nanoparticles 107 are separated by a dielectric 210. A transparent conductive oxide (TCO) 212 is used to form an ohmic contact, and the TCO 212 may comprise a thin metal scheme such as Ni, Nu/Au etc. The metal layer is kept thin compared to the TCO 212 to reduce optical losses. A noble metal 107 such as silver is then deposited to be used as a reflective layer. A separate metal pad scheme then may be adopted to allow flip chip bonding. Following remelting and soldering, the gaps 213 may be filled with electrically insulating adhesive. Thermal compression bonding is an alternative.

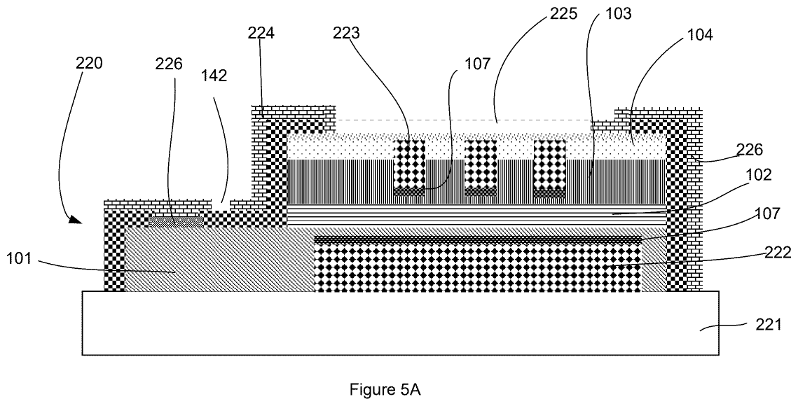

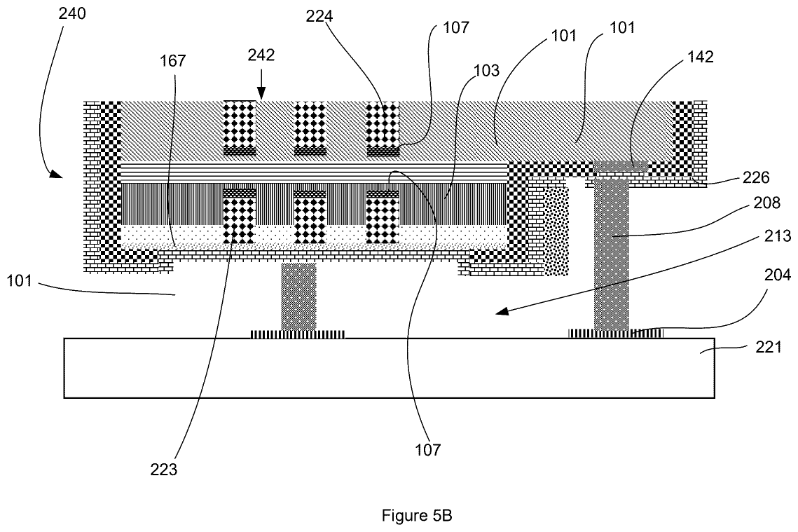

In FIG. 5A, there is shown a semiconductor device 220 fabricated on substrate 221, with plasmonic particles processed on p-GaN. The device 200 also contains an etched region 222 on the n-side where a noble metal layer 107 is deposited. The noble can then have a spacer layer 223 which can be dielectric to isolate the nanoparticle, or it can be conducting layer such as TCO which can improve hole injection efficiency of holes. The choice of material 223 needs to be carefully chosen as to minimize its interference with the plasmonic properties of the nanoparticle. This creates a plasmonic nanocavity effect, which requires a thin active region 102.

The rate enhancement arises from a plasmonic nanocavity structure with a small mode volume, which generates highly intensified localized electromagnetic fields near the thin active region, boosting the transition rate (known as the Purcell effect). Furthermore, this MQW-coupled plasmonic metasurface efficiently generates directional emission with an ultrafast response time, enabling modulation at speeds that surpass conventional limits. The p and n contact are separate by an electrical isolation region 224. In this configuration light is emitting from the top open side of mesa 225. The mesa and sidewall are covered with the contact pads 226 with one possible scheme such as chromium and gold. This prevents the light from scaping the sidewall thus reducing crosstalk between neighbouring devices. For light emitting diodes array-based system crosstalk reduction can significantly improve data communication.

In FIG. 5B, there is shown a semiconductor device 240 fabricated on substrate 241, comprising plasmonic particles processed on both the p-side 223 and n-side 224 of the device 240, such as a LED. This enables plasmonic effects to be enhanced from both sides and, in certain scenarios, allows plasmonic coupling with plasmonic nanoparticles on both sides of the active region, significantly boosting the field strength. The device 240 in this configuration emits from the top side 242 without significant reduction in light extraction efficiency while enjoying the enhanced plasmonic effects introduced by the plasmonic nanostructure. The top and bottom structures can be aligned to enhance the plasmonic effects can be made to work independently.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

### REFERENCES

[1] Gontijo, I., Boroditsky, M., Yablonovitch, E., Keller, S., Mishra, U. K., & DenBaars, S. P. (1999). Coupling of InGaN quantum-well photoluminescence to silver surface plasmons. Physical Review B, 60 (16), 11564.
[2] Okamoto, K., & Kawakami, Y. (2009). High-efficiency InGaN/GaN light emitters based on nanophotonics and plasmonics. IEEE Journal of selected topics in quantum electronics, 15 (4), 1199-1209.
[3] Kwon, M. K., Kim, J. Y., Kim, B. H., Park, I. K., Cho, C. Y., Byeon, C. C., & Park, S. J. (2008). Surface-plasmon-enhanced light-emitting diodes. Advanced Materials, 20 (7), 1253-1257.
[4] Henson, J., Dimakis, E., DiMaria, J., Li, R., Minissale, S., Dal Negro, L., . . . & Paiella, R. (2010). Enhanced near-green light emission from InGaN quantum wells by use of tunable plasmonic resonances in silver nanoparticle arrays. Optics express, 18 (20), 21322-21329.
[5] Ferrari, L., Smalley, J. S., Qian, H., Tanaka, A., Lu, D., Dayeh, S., . . . & Liu, Z. (2018). Design and analysis of blue InGaN/GaN plasmonic LED for high-speed, high-efficiency optical communications. ACS Photonics, 5 (9), 3557-3564.
[6] Lu, C. H., Lan, C. C., Lai, Y. L., Li, Y. L., & Liu, C. P. (2011). Enhancement of Green Emission from InGaN/GaN Multiple Quantum Wells via Coupling to Surface Plasmons in a Two-Dimensional Silver Array. Advanced Functional Materials, 21 (24), 4719-4723.
[7] Chen, Z., Deng, C., Xi, X., Chen, Y., Feng, Y., Jiang, S., . . . & Shen, B. (2021). Study on localized surface plasmon coupling with many radiators. Nanomaterials, 11 (11), 3105.
[8] Traverso, A. J., Huang, J., Peyronel, T., Yang, G., Tiecke, T. G., & Mikkelsen, M. H. (2021). Low-loss, centimeter-scale plasmonic metasurface for ultrafast optoelectronics. Optica, 8 (2), 202-207.

1. A method for fabricating a semiconductor device, the method comprising the steps of:
providing a substrate;
patterning nanoholes through a p-doped GaN layer down towards a multiple quantum well (MQW) emitting region of a noble metal;
depositing a nanostructured noble metal film in the nanoholes.

2. The method of claim 1, wherein the texturing comprises etching.

3. The method of claim 1, wherein the holes are at least one of a vertical or angled profile.

4. The method of claim 1, wherein the semiconductor device comprises a plasmonic III-Nitride device epi-structure.

5. The method of claim 4, wherein the plasmonic III-Nitride device structure comprises a plasmonic region comprising the nanoholes and an electronic region free of the nanoholes.

6. The method of claim 1, further comprising a step of maximizing a near-field coupling between the multiple quantum well (MQW) emitting region and the p-GaN layer/noble metal interface supporting a surface plasmon when a distance between the near-field coupling and the multiple quantum well (MQW) emitting region is minimized.

7. The method of claim 6, wherein the distance of plasmonic nanoparticle from the nearest quantum well of the multiple quantum well (MQW) emitting region is less than a penetration depth of the surface plasmon.

8. The method of claim 7, wherein the distance of plasmonic nanoparticle from the nearest quantum well of the multiple quantum well (MQW) emitting region is less than about 50 nm at wavelength of about 450 nm.

9. The method of claim 8, wherein the p-GaN layer is thicker than a depletion width on a p-side of the diode to facilitate carrier transport.

10. The method of claim 9, wherein the p-GaN layer is approximately more than 50 nm with sufficient doping levels in the p and n regions.

11. The method of claim 6, wherein the nanostructured noble metal film couples the surface plasmon to increase radiative recombination rates without sacrificing significantly p-contact resistance.

12. The method of claim 1, wherein the semiconductor device comprises at least one of a buffer layer, a superlattice strain relief layer, a low doped high material quality n-doped layer, a high doped low temperature grown p-doped layer, a heavily doped high temperature grown p-doped layer, and an aluminum gallium nitride based larger bandgap electron blocking layer.

13. A method for fabricating a semiconductor device, the method comprising the steps of:
providing a substrate;
activating a top p-doped layer comprising at least one step of metal deposition, rapid thermal annealing and chemical wet etching;
etching features into the p-doped layer using a thin dielectric and resist as a mask;
depositing a passivation layer and/or a noble metal into the etched features; and
fabricating the semiconductor device a flip chip bonding process.

14. The method of claim 13, comprising a further step of etching the features into the p-doped layer with various 3D geometric shapes to improve plasmonic coupling.

15. The method of claim 13, comprising a further step of etching the features into the p-doped layer with a positive angle profile for closer proximity to at least one quantum well.

16. The method of claim 13, comprising a further step of etching the features into the p-doped layer with a negative angle profile for a reduced semiconductor/metal interface, thereby minimizing surface recombination and contact resistance.

17. The method of claim 13, comprising a further step of removing deposited metal on an un-etched p-doped surface to improve light extraction.

18. The method of claim 13, comprising a further step of depositing an intermediate layer before depositing the noble metal to finely tune resonance energy of a plasmonic nanoparticle.

19. The method of claim 13, comprising a further step of depositing a passivation layer at a noble metal/semiconductor interface to reduce surface recombination velocity.

20. The method of claim 13, comprising a further step of partially filling the etched features with the noble metal for enhanced plasmonic effect.

21. The method of claim 13, comprising a further step of completely filling the etched features with the noble metal for plasmonic coupling and enhanced reflection.

22. The method of claim 13, comprising a further step of adjusting at least one of a size of nanoparticles, a geometry or periodicity of metallic nanostructures and employing different metallic configurations to tune a surface plasmon frequency and to reduce a spectral linewidth of the device.

23. The method of claim 13, comprising a further step of injecting carriers into an active region for accumulation of excess minority carriers and reduce diffusion capacitance at high bias conditions in presence of defect states in the p-doped layer.

24. The method of claim 13, wherein the device is a top emitting light emitting device having plasmonic features.

25. The method of claim 13, wherein the device is a bottom emitting flip chip bonded light emitting device having plasmonic features for enhanced light extraction, improved heat dissipation and reduced radiative recombination rates.

26. The method of claim 13, wherein the device is a bottom emitting flip chip bonded light emitting device with plasmonic features comprises a transparent conductive oxide for reduced optical losses, enhanced light extraction and reduced radiative recombination rates.

27. A method for fabricating a semiconductor device, the method comprising the steps of:
providing a substrate;
activating a top p-doped layer;
etching grooves on the p-doped layer;
partially or fully filling the grooves with a metal; and
fabricating the semiconductor device via a flip chip bonding process.

28. The method of claim 27, wherein the semiconductor device is a top emitting flip chip light emitting device.

29. The method of claim 27, wherein the semiconductor device is a bottom emitting flip chip light emitting device.

30. The method of claim 27 wherein the semiconductor device comprises a III-Nitride based light emitting device epi-structure.

31. A semiconductor device comprising:
on a substrate, a light emitting device (LED) epi-structure comprising
a n-doped layer,
a multi quantum well (MQW);
a p-doped layer,
an active region;
a metal on top of the p-doped layer;
etched features within the p-doped layer with various 3D geometric shapes to improve plasmonic coupling.

32. The semiconductor device of claim 31, wherein the etched features comprise a positive angle profile.

33. The semiconductor device of claim 31, wherein the etched features comprise a negative angle profile.

34. The semiconductor device of claim 31, wherein the semiconductor device is a top emitting flip chip light emitting device.

35. The semiconductor device of claim 31, wherein the semiconductor device is a bottom emitting flip chip light emitting device.

36. The semiconductor device of claim 35, further comprising a transparent conductive oxide for reduced optical losses, enhanced light extraction and reduced radiative recombination rates.

37. The semiconductor device of claim 31, further comprising a noble metal contained with the etched features for enhanced plasmonic effect.

38. The semiconductor device of claim 37, further comprising an intermediate layer.

39. The semiconductor device of claim 38, further comprising a passivation layer at a noble metal/semiconductor interface to reduce surface recombination velocity.

40. The semiconductor device of claim 31, wherein the semiconductor device comprises a III-Nitride based light emitting device epi-structure.
